(19) United States
(12) Patent Application Publication
(10) Pub. No.: US 2025/0098290 A1
(43) Pub. Date: Mar. 20, 2025

(54) HIGH-VOLTAGE DEVICE AND METHOD OF FORMING THE SAME

(71) Applicant: Nuvoton Technology Corporation, Hsinchu Science Park (TW)

(72) Inventors: Vivek NINGARAJU, Kuvempunagar (IN); Chin-Han PAN, Hsinchu City (TW); Hong-Xiu CHEN, Hsinchu City (TW)

(21) Appl. No.: 18/883,030

(22) Filed: Sep. 12, 2024

(30) Foreign Application Priority Data
Sep. 14, 2023 (TW) 112135019

(51) Int. Cl. H01L 27/06; H01L 21/225; H01L 21/265; H01L 29/06; H01L 29/66; H01L 29/808; H01L 29/861

(52) U.S. Cl. CPC H10D 84/811; H01L 21/2253; H01L 21/26513; H10D 8/043; H10D 8/411; H10D 30/0512; H10D 30/83; H10D 62/107

(57) ABSTRACT

A high-voltage device includes: a diode; a junction field-effect transistor (JFET) adjoining the diode and electrically coupled to the diode; a high-voltage junction termination (HVJT) element electrically connected with the diode and the junction field-effect transistor, wherein the high-voltage junction termination element is a ring shape from top view, and a high-side region and a low-side region are respectively defined inside the ring shape and outside the ring shape; and a first deep well region encircling the high-side region. The first deep well region includes: a first segment disposed in the high-voltage junction termination element; and a second segment disposed in the junction field-effect transistor. The first segment includes a well region and a doped region in the well region. The second segment includes only the well region.

### CROSS REFERENCE TO RELATED APPLICATIONS

This application claims priority of Taiwan Patent Application No. 112135019, filed Sep. 14, 2023, the entirety of which is incorporated by reference herein.

### BACKGROUND

### Technical Field

The present disclosure relates to a high-voltage device and a method of forming the same, and in particular, to adjusting the active region to improve the electric field crowding issue.

### Description of the Related Art

In most switching applications, switching efficiency depends on switching loss and switching speed. One of the means of using the high-voltage circuit to supply power to the gate driver is the use of a bootstrap circuit, which demonstrates the advantages of simplicity and low cost. The bootstrap circuit includes a bootstrap diode (BSD), a bootstrap capacitor (BSC), and a bootstrap resistor (BSR), and the voltage level for the high-voltage circuit may be supplied.

Although high-voltage devices have been generally adequate for their intended purposes, they have not been entirely satisfactory in all respects. For example, the breakdown voltage needs to be further improved. Therefore, there remain issues regarding the high-voltage device and the manufacture thereof that still need to be addressed.

### SUMMARY

An embodiment of the present disclosure provides a high-voltage device, the high-voltage device includes: a diode; a junction field-effect transistor (JFET) adjoining the diode and electrically coupled to the diode; a high-voltage junction termination (HVJT) element electrically connected to the diode and the junction field-effect transistor, wherein the high-voltage junction termination element is a ring shape from a top view, and a high-side region and a low-side region are respectively defined inside the ring shape and outside the ring shape; and a first deep well region encircling the high-side region. The first deep well region includes: a first segment disposed in the high-voltage junction termination element; and a second segment disposed in the junction field-effect transistor. The first segment includes a well region and a doped region in the well region. The second segment includes only the well region.

Another embodiment of the present disclosure provides a method of forming a high-voltage device, the method includes providing a substrate; forming an epitaxial layer on the substrate; and forming a first high-voltage well region, a first deep well region encircling the first high-voltage well region, and a second high-voltage well region encircling the first deep well region in a first region of the epitaxial layer; forming a first doped region and a second doped region encircling the first doped region in the first high-voltage well region; forming a third doped region in the first deep well region, wherein the third doped region encircles the second doped region; forming a fourth doped region in the second high-voltage well region. The method further includes: forming a fifth doped region and a sixth doped region in a second region of the epitaxial layer, wherein the second region laterally adjoins the first region; extending one side of the fourth doped region outward into a third region of the epitaxial layer to form a loop, wherein the second region is in the loop; forming a second deep well region in the loop, the second deep well region extends along an inner side of the loop and across the second region; forming a seventh doped region in the second deep well region, wherein the seventh doped region extends along a profile of the second deep well region; and cutting off a portion of the seventh doped region in the second deep well region across the second region.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a top view of a high-voltage device, according to some embodiments of the present disclosure.

FIG. 2 is an enlarged view of the high-voltage device illustrated in FIG. 1, according to some embodiments of the present disclosure.

FIG. 3 is a cross-sectional view of a high-voltage device, according to some embodiments of the present disclosure.

FIG. 4 is a cross-sectional view of a high-voltage device, according to some embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity, and does not in itself dictate a relationship between various embodiments and/or configuration discussed.

Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact.

Furthermore, spatially relative terms, such as “beneath,” “below,” “lower,” “on,” “above,” “upper,” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean ±20% of the stated value, more typically ±10% of the stated value, more typically ±5% of the stated value, more typically ±3% of the stated value, more typically ±2% of the stated value, more typically ±1% of the stated value, and even more typically ±0.5% of the stated value. The stated value of the present disclosure is an approximate value. That is, when there is no specific description of the terms “about,” “approximately” and “substantially”, the stated value includes the meaning of “about,” “approximately” or “substantially”.

Some embodiments of the disclosure are described. Additional operations can be provided before, during, and/or after the stages described in these embodiments. Additional features can be added to the high-voltage device structure. Some of the features described below can be replaced or eliminated for different embodiments. Although some embodiments are discussed with operations performed in a particular order, these operations may be performed in another logical order.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

In order to enhance switching efficiency, a bootstrap circuit may be incorporated into a high-voltage device, and the bootstrap circuit includes a bootstrap diode (BSD), a bootstrap capacitor (BSC), and a bootstrap resistor (BSR). The critical parameters of the bootstrap diode of the bootstrap circuit are reverse recovery time, forward voltage drop, and reverse blocking voltage. In conventional designs, the bootstrap diode is typically discrete. The discrete bootstrap diode is placed outside the high-voltage device, and is individually connected to the high-side region and the low-side region. In order to meet the requirement of cut-off voltage, the bootstrap diode must be fabricated through a loosened design rule, which in turn causing a larger device dimension. Since the discrete bootstrap diode is not integrated into the high-voltage device, an excessively large space may be occupied, and the cost of additional bills of materials (BOM) may be increased. Therefore, the embedded bootstrap diode that is integrated into the high-voltage device may be implemented to address the above issue. However, in comparison with the discrete bootstrap diode, the embedded bootstrap diode during operation may generate a forward leakage from the anode terminal to the substrate (the vertical bipolar junction), while the cathode terminal without a bipolar junction has no notable reverse leakage. Therefore, an isolation element (for example, a buried layer) may be further added into the embedded bootstrap diode to reduce the generation of the forward leakage.

When the high-voltage device integrates an embedded bootstrap diode, a junction field-effect transistor (JEFT), and a high-voltage junction termination (HVJT) element together, the structural difference may lower the breakdown voltage of the overall high-voltage device. Due to the integration of the different structures, the overall circuit design (especially at the interface between different elements) has become relatively complex. For example, the peripheral doped region of the high-voltage junction termination element and the drain-doped region of the junction field-effect transistor may be located at different positions. In the process of integration, the peripheral doped region and the drain-doped region need to be extended with curved profiles for the connection between them to be achieved. From the result of the hot spot analysis, the overlying metal layer corresponding to the corner of the doped region (or the active region) may readily gather excessively high electric field due to the dimensional change, which is determined as the main factor for causing low breakdown. It should be appreciated that the drain-doped region is normally the terminal for applying high-voltages, thus may have a direct impact on the breakdown voltage performance. The inventor has discovered that the drain-doped region of the junction field-effect transistor may be removed to avoid the electric field crowding issue, which can in turn enhance the breakdown voltage.

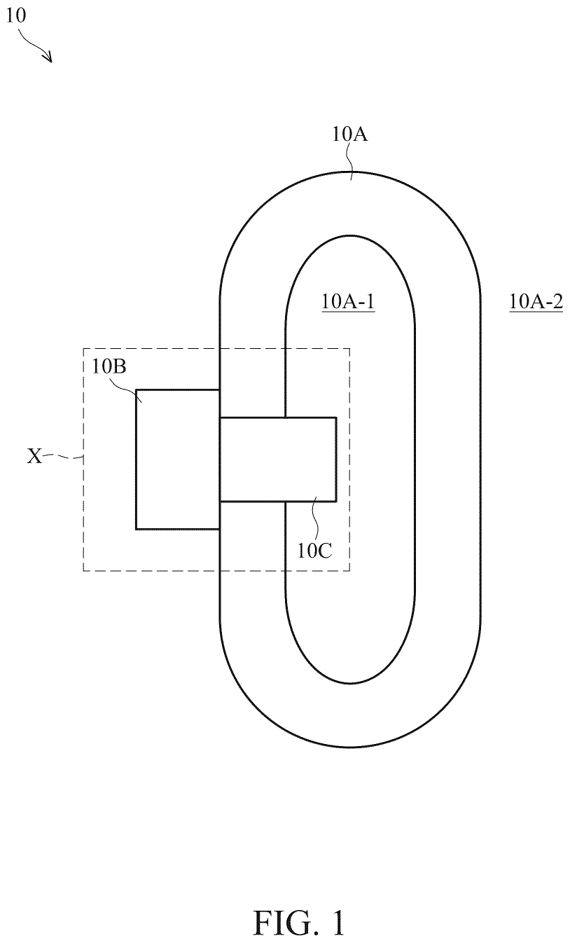

FIG. 1 is a top view of a high-voltage device 10, according to some embodiments of the present disclosure. In some embodiments, a high-voltage device may typically include any quantity of active components or passive components. The active components include metal-oxide semiconductor (MOS) transistors, complementary metal-oxide semiconductor (CMOS) transistors, lateral-diffused metal-oxide semiconductor (LDMOS) transistors, bipolar complementary metal oxide semiconductor-double diffused metal oxide semiconductor (BCD) transistors, bipolar junction transistor (BJT), planar transistors, fin field-effect transistors (finFET), gate-all-around field-effect transistors (GAA FET), the like, or a combination thereof. The passive components include metal lines, capacitors, inductors, resistors, diodes, bonding pads, or the like.

Referring to FIG. 1, the high-voltage device 10 may include a high-voltage junction termination element 10A, a diode 10B, and a junction field-effect transistor 10C. The junction field-effect transistor 10C may be adjoined and electrically coupled to the diode 10B, while the high-voltage junction termination element 10A may be electrically connected to the diode 10B and the junction field-effect transistor 10C. The high-voltage device 10 may be a laterally diffused configuration. In some embodiments, the high-voltage junction termination element 10A may be designed into a ring shape from top view. A high-side region 10A-1 may be defined inside the ring shape of the high-voltage junction termination element 10A, while a low-side region 10A-2 may be defined outside the ring shape of the high-voltage junction termination element 10A. Moreover, the diode 10B may be an embedded bootstrap diode. Integrating the high-voltage junction termination element 10A, the diode 10B, and the junction field-effect transistor 10C may result in smaller chip area and higher reliability. For example, since the high-voltage junction termination element 10A, the diode 10B, and the junction field-effect transistor 10C share the same chip space, the overall area of the high-voltage device 10 may be effectively conserved. Furthermore, the integrated configuration allows the high-voltage junction termination element 10A, the diode 10B, and the junction field-effect transistor 10C to be electrically coupled to each other, thus the wire bonding and the opening formation may be omitted, leading to the reliability enhancement.

Still referring to FIG. 1, even though the high-voltage junction termination element 10A is illustrated as an elliptical ring shape, but the present disclosure is not limited thereto. For example, the high-voltage junction termination element 10A may be circular ring shape, square ring shape, rectangular ring shape, triangular ring shape, or any suitable closed geometrical ring shape. The ring shape configuration allows the integration of the high-voltage junction termination element 10A with the diode 10B and the junction field-effect transistor 10C to become more efficient without occupying additional chip area. The high-voltage junction termination element 10A physically and electrically isolates the high-side region 10A-1 and the low-side region 10A-2. The high-side region 10A-1 may embody the components to be operated under high-voltage levels, while the low-side region 10A-2 may embody components to be operated under low-voltage levels. Typically, the term “high-voltage” refers to a voltage above 300V, for example, between 300V and 1200 A, between 300V and 750V, or between 750V and 1200V. The term “low-voltage” refers to a voltage below 20V, for example, between 1V and 20V, between 1V and 10V, or between 10V and 20V. In a specific embodiment of the present disclosure, the high-side region 10A-1 and the low-side region 10A-2 may be operated under the voltage of 600V and 15V, respectively.

Referring to FIG. 1, the diode 10B may span across the anode terminal of a first conductive type and the cathode terminal of a second conductive type. The second conductive type is different from the first conductive type. In the following embodiments, the first conductive type and the second conductive type may represent p-type and n-type, respectively. The first conductive type (p-type) and the second conductive type (n-type) may be respectively doped with suitable dopants (or impurities). P-type dopants may include boron (B), indium (In), aluminum (Al), and gallium (Ga), while n-type dopants may include phosphorus (P) and arsenic (As). As mentioned previously, in order to prevent the forward leakage generated from the anode terminal to the substrate (the vertical bipolar junction), the buried layer, for example, may be added to suppress the substrate leakage under 1%. As a result, the device construction coupled to the diode 10B and the junction field-effect transistor 10C may sustain a reverse blocking voltage of 650V and a forward current of 17 mA. Furthermore, the recovery time required from the on-state to the off-state of the diode 10B may be between 10 nsec and 50 nsec.

Still referring to FIG. 1, the junction field-effect transistor 10C may include a junction under the gate active region, in which the electric field may be applied to function as the gate terminal. The junction field-effect transistor 10C may be designed into the depletion mode (normally-on and conducting state under the gate voltage of 0V), or may be designed into enhance mode (normally-off state under the gate voltage of 0V). During the operation of the junction field-effect transistor 10C, the current flows from the source terminal, passing by under the gate terminal, to the drain terminal. It should be appreciated that the operation of the junction field-effect transistor 10C is opposite from that of the metal-oxide semiconductor field-effect transistor (MOSFET). For example, as the gate voltage of the junction field-effect transistor 10C increases, the depletion area diffuses to cut off conducting path to suppress the current. Without integrating with the high-voltage junction termination element 10A and the diode 10B, the junction field-effect transistor 10C may have a circular design, for example, having a drain center circle, with a gate ring shape, a source ring shape, and a bulk ring shape sequentially encircling the drain center circle. Such design may prevent sharp edge effect, which may cause device failure. Furthermore, the circular design may also allow the electric field to be more uniformly distributed.

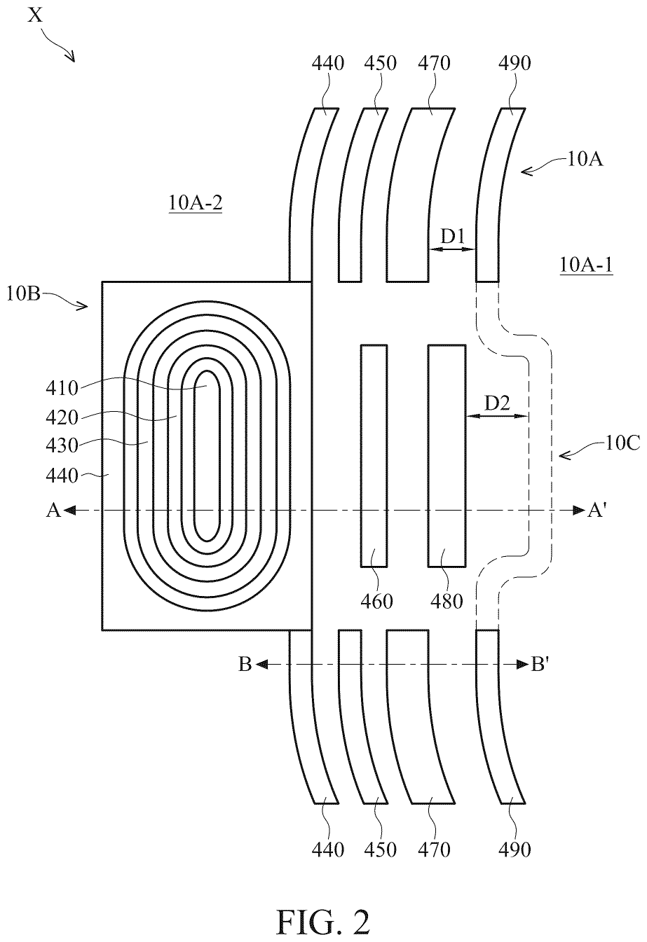

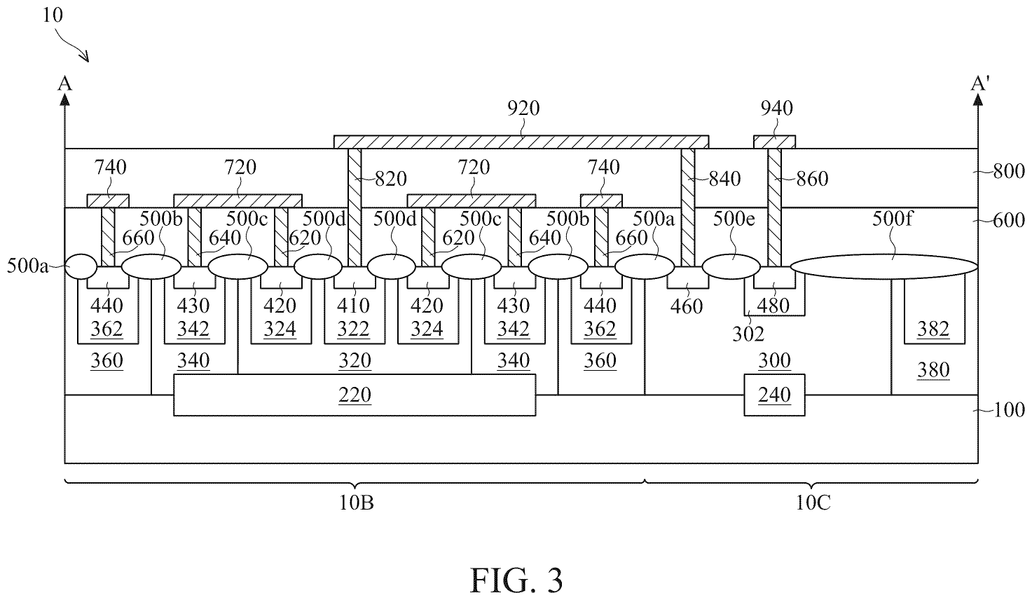

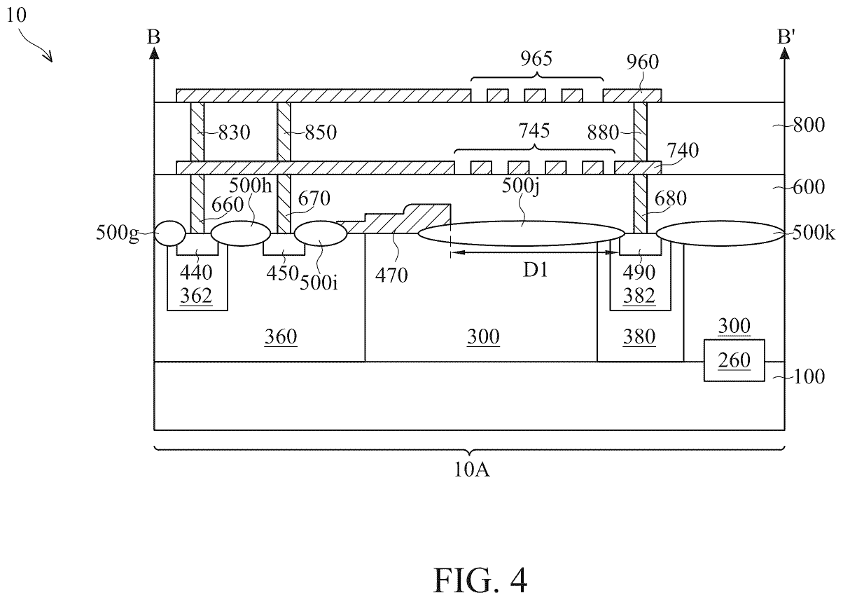

FIG. 2 is an enlarged view of a region X labeled in FIG. 1, according to some embodiments of the present disclosure. FIG. 3 is a cross-sectional view of the high-voltage device 10, according to some embodiments of the present disclosure. FIG. 4 is a cross-sectional view of the high-voltage device 10, according to some embodiments of the present disclosure. It should be noted that FIG. 3 is the cross-sectional view obtained from a line A-A′ of FIG. 2, while FIG. 4 is the cross-sectional view obtained from a line B-B′ of FIG. 2. For simplicity, FIG. 2 only illustrates the layout of all active regions (for example, the doped regions) in the high-voltage junction termination element 10A, the diode 10B, and the junction field-effect transistor 10C. The line A-A′ span across the diode 10B and the junction field-effect transistor 10C, while the line B-B′ span across the high-voltage junction termination element 10A.

Referring FIGS. 2-4, the high-voltage device 10 may include a substrate 100, a buried layer 220, a buried layer 240, a buried layer 260, an epitaxial layer 300, a conductive structure 470, an isolation structure 500a, an isolation structure 500b, an isolation structure 500c, an isolation structure 500d, an isolation structure 500e, an isolation structure 500f, an isolation structure 500g, an isolation structure 500h, an isolation structure 500i, an isolation structure 500j, an isolation structure 500k, an interlayer dielectric (ILD) layer 600, a via 620, a via 640, a via 660, a via 670, a via 680, a metal layer 720, a metal layer 740, an inter-metal dielectric (IMD) layer 800, a via 820, a via 830, a via 840, a via 850, a via 860, a via 880, a metal layer 920, a metal layer 940, and a metal layer 960.

In some embodiments, the epitaxial layer 300 may include a well region 302, a high-voltage well region 320, a deep well region 340, a high-voltage well region 360, a deep well region 380, and a doped region 460. The high-voltage well region 320 may include a well region 322 and a well region 324. The deep well region 340 may include a well region 342. The high-voltage well region 360 may include a well region 362 and a doped region 450. The deep well region 380 may include a well region 382. The well region 322 may include a doped region 410. The well region 324 may include a doped region 420. The well region 342 may include a doped region 430. The well region 362 may include a doped region 440. The well region 302 may include a doped region 480. The well region 382 may include a doped region 490. It is worth noted that the substrate 100, the epitaxial layer 300, the interlayer dielectric layer 600, and the inter-metal dielectric layer 800 may be disposed across the high-voltage junction termination element 10A, the diode 10B, and the junction field-effect transistor 10C.

Referring to FIG. 2, the high-voltage junction termination element 10A may include the doped region 440, the doped region 450, the conductive structure 470, and the doped region 490. The diode 10B may include the doped region 410, the doped region 420, the doped region 430, and the doped region 440. The junction field-effect transistor 10C may include the doped region 460 and the doped region 480. It is worth noted that the doped region 420 encircles the doped region 410, the doped region 430 encircles the doped region 420, and the doped region 440 encircles the doped region 430. Moreover, one side of the doped region 440 extends outward to form a loop. In other words, the doped region 440 may span across the high-voltage junction termination element 10A and the diode 10B, and in direct contact with the low-side region 10A-2.

In conventional circuitry, the doped region 490 may span across the high-voltage junction termination element 10A and the junction field-effect transistor 10C, and is adjacent to the high-side region 10A-1. Based on the circuit design rule, the segment of the doped region 490 at the high-voltage junction termination element 10A (for example, the peripheral doped region) needs to be spaced apart from the conductive structure 470 by a distance D1 in the horizontal direction, and the segment of the doped region 490 at the junction field-effect transistor 10C (for example, the drain-doped region) needs to be spaced apart from the doped region 480 by a distance D2 in the horizontal direction. Since the positions of the conductive structure 470 and the doped region 480 are different, and the distance D1 and the distance D2 are different, the segment of the doped region 490 at the high-voltage junction termination element 10A and the segment of the doped region 490 at the junction field-effect transistor 10C are unable to align with each other. As mentioned previously, the doped region 490 needs to have the curved profile to connect the segment at the high-voltage junction termination element 10A and the segment at the junction field-effect transistor 10C. However, from the result of the hot spot analysis, the corner of the doped region 490 and the overlying metal layer 960 corresponding to the corner may readily gather excessively high electric field, which leads to lower breakdown voltage. Typically, due to the reliability consideration, the overall device breakdown voltage needs to be about 20% higher than the predetermined operational voltage. The inventor has discovered that even if the profile of the corner that is designed to have a larger radius of curvature may alleviate the electric field gathering, but the improvement on the breakdown voltage is still inadequate.

According to some embodiments of the present disclosure, the segment of the doped region 490 at the junction field-effect transistor 10C may be removed to avoid the electric field crowding issue. The removal of the segment of the doped region 490 at the junction field-effect transistor 10C may allow the portion of the curved profile to be omitted. For illustrative purpose, the removed portion of the doped region 490 is labeled with dotted lines (as shown in FIG. 2). Even if the segment of the original loop of the doped region 490 at the field effect-transistor 10C is cut off, the loop can still remain conducting through the deep well region 380 (as shown in FIGS. 3 and 4). More specifically, the electrical connection between the two ends of the doped region 490 resulted from the segment removal may be established using the deep well region 380. When the electric field crowding issue is effectively alleviated, the overall breakdown voltage of the high-voltage device 10 may be enhanced.

Referring to FIGS. 3 and 4, the substrate 100 may be, for example, a wafer or a chip, but the present disclosure is not limited thereto. In some embodiment, the substrate 100 may be a semiconductor substrate, for example, silicon (Si) substrate. Furthermore, in some embodiments, the semiconductor substrate may also be an elemental semiconductor including germanium (Ge), a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb), an alloy semiconductor including silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenide phosphide (GaInAsP) alloy, or a combination thereof.

In other embodiments, the substrate 100 may also be a semiconductor on insulator (SOI) substrate. The semiconductor on insulator substrate may include a base plate, a buried oxide (BOX) layer disposed on the base plate, and a semiconductor layer disposed on the buried oxide layer. In a specific embodiment of the present disclosure, the substrate 100 may be the first conductive type (p-type), with a doping concentration between 1×10¹⁴ cm⁻³ and 3×10¹⁴ cm⁻³.

In other embodiments, the substrate 100 may include isolation structures (not shown) to define active regions and to electrically isolate active region elements within or above the substrate 100, but the present disclosure is not limited thereto. The isolation structures may include deep trench isolation (DTI) structures, shallow trench isolation (STI) structures, or local oxidation of silicon (LOCOS) structures. In some embodiments, the formation of the isolation structures may include, for example, forming an insulating layer on the substrate 100, selectively etching the insulating layer and the substrate 100 to form trenches that extend from the top surface of the substrate 100 to a position within the substrate 100, in which the trenches are located between adjacent active regions. Next, the formation of the isolation structures may include growing rich nitrogen-containing (such as silicon oxynitride (SiON) or the like) liners along the trenches, followed by filling insulating materials (such as silicon dioxide (SiO₂), silicon nitride (SiN), silicon oxynitride, or the like) into the trenches with deposition processes. After that, an annealing process is performed on the insulating materials in the trenches, followed by a planarization process (such as chemical mechanical polish (CMP)) on the substrate 100 to remove excessive insulating materials, so the insulating materials in the trenches are level with the top surface of the substrate 100.

Still referring to FIGS. 3 and 4, the epitaxial layer 300 is formed on the substrate 100. According to some embodiments of the present disclosure, the epitaxial layer 300 may have the second conductive type (n-type), with a doping concentration between 1.13×10¹⁵ cm⁻³ and 2.30×10¹⁵ cm⁻³. In a specific embodiment of the present disclosure, the substrate 100 and the epitaxial layer 300 may have different conductive types, and the doping concentration of the substrate 100 is smaller than that of the epitaxial layer 300. The materials of the epitaxial layer 300 may include silicon, silicon germanium, silicon carbide, the like, or a combination thereof. The thickness of the epitaxial layer 300 may be between 3 μm and 7 μm. The epitaxial layer 300 may be formed by epitaxial process, which may include metal organic chemical vapor deposition (MOCVD), hydride vapor phase epitaxy (HVPE), molecular beam epitaxy (MBE), the like, or a combination thereof.

Referring to FIGS. 3 and 4, the high-voltage device 10 may include the buried layer 220, the buried layer 240, and the buried layer 260 disposed in the substrate 100. In some embodiments, the buried layer 220, the buried layer 240, and the buried layer 260 may be located in the diode 10B, the junction field-effect transistor 10C, and the high-voltage junction termination element 10A, respectively. The buried layer 220 may directly contact the high-voltage well region 320 and the deep well region 340 of the epitaxial layer 300, while the buried layer 240 and the buried layer 260 may directly contact the epitaxial layer 300. According to some embodiments of the present disclosure, the buried layer 220 may help lowering the leakage from the anode terminal of the diode 10B to the substrate 100, the buried layer 240 may increase the channel space of the junction field-effect transistor 10C to sustain a higher current, and the buried layer 260 may form an n-type liner of the high-side region 10A-1. It is worth noted that a larger channel space will require a higher pinch-off voltage to close the channel. The buried layer 220, the buried layer 240, and the buried layer 260 have the second conductive type (n-type). The doping concentration of the buried layer 220, the buried layer 240, and the buried layer 260 may be between 6.4×10¹⁶ cm⁻³ and 9.6×10¹⁶ cm⁻³. The vertical dimension of the buried layer 220, the buried layer 240, and the buried layer 260 may be between 1 μm and 2 μm. The lateral dimension of the buried layer 220 may span across the high-voltage well region 320 and the deep well region 340 of the epitaxial layer 300. The lateral dimension of the buried layer 240 may be similar to that of the well region 302. The lateral dimension of the buried layer 260 may span across the entire high-side region 10A-1.

The formation of the buried layer 220, the buried layer 240, and the buried layer 260 may include ion implanting n-type dopants (for example phosphorus or arsenic) in the substrate 100 and performing thermal treatment to drive in the implanted ions into the substrate 100 before forming the epitaxial layer 300. After that, the epitaxial layer 300 may then be formed on the substrate 100. In some embodiments, since the epitaxial layer 300 is formed under the high temperature condition, thus the implanted ions may be diffused into the epitaxial layer 300. As shown in FIGS. 3 and 4, the buried layer 220, the buried layer 240, and the buried layer 260 are located near the interface between the substrate 100 and the epitaxial layer 300, with a portion in the substrate 100, and another portion in the epitaxial layer 300. In other words, the buried layer 220, the buried layer 240, and the buried layer 260 may be extended upward from the interface between the substrate 100 and the epitaxial layer 300.

Still referring to FIGS. 3 and 4, the high-voltage well region 320, the deep well region 340, the high-voltage well region 360, and the deep well region 380 may be formed in the epitaxial layer 300. In some embodiments, the high-voltage well region 320 and the deep well region 340 may be located in the diode 10B, the high-voltage well region 360 may be located in the high-voltage junction termination element 10A and the diode 10B, and the deep well region 380 may be located in the high-voltage junction termination element 10A and the junction field-effect transistor 10C. It should be appreciated that the deep well region 340 encircles the high-voltage well region 320 from top view, so the deep well region 340 is disposed on both sides of the high-voltage well region 320 in the cross-sectional view. Similarly, the high-voltage well region 360 encircles the deep well region 340 from top view, so the high-voltage well region 360 is disposed on both outer sides of the deep well region 340. The high-voltage well region 320, the deep well region 340, the high-voltage well region 360, and the deep well region 380 may be vertically extended from the upper surface of the epitaxial layer 300 to the interface between the epitaxial layer 300 and the substrate 100, or to the interface between the epitaxial layer 300 and the buried layer 220. According to some embodiments of the present disclosure, the high-voltage well region 320 and the high-voltage well region 360 may be the first conductive type (p-type), and the deep well region 340 and the deep well region 380 may be the second conductive type (n-type). Since the high-voltage well region 320 of the first conductive type is encircled by the deep well region 340 of the second conductive type, and the deep well region 340 is further encircled by the high-voltage well region 360 of the first conductive type, thus a bipolar (PNP) junction may be constituted.

The high-voltage well region 320, the deep well region 340, the high-voltage well region 360, and the deep well region 380 may be formed by the ion implantation and/or the diffusion process. In alternative embodiments, instead of using the ion implantation and/or the diffusion process, the high-voltage well region 320, the deep well region 340, the high-voltage well region 360, and the deep well region 380 may be in situ doped during the growth of the epitaxial layer 300. In yet other embodiments, in situ and implantation doping may be implemented together.

In some embodiments, the high-voltage well region 320 may be located above the buried layer 220. More specifically, the high-voltage well region 320 may be in direct contact with the buried layer 220 in the vertical direction. The doping concentration of the high-voltage well region 320 may be between 1.6×10¹⁶ cm⁻³ and 2.4×10¹⁶ cm⁻³. As mentioned previously, the high-voltage well region 320 may include the well region 322 and the well region 324. It should be appreciated that the well region 324 encircles the well region 322 from top view, so the well region 324 is disposed on both sides of the well region 322 in the cross-sectional view.

In some embodiments, the deep well region 340 may laterally encircle the high-voltage well region 320, and may be partially above the buried layer 220. More specifically, the deep well region 340 may be in direct contact with the buried layer 220 in the vertical direction, and the deep well region 340 may be between the high-voltage well region 320 and the high-voltage well region 360 in the horizontal direction. The doping concentration of the deep well region 340 may be between 3.6×10¹⁶ cm⁻³ and 5.4×10¹⁶ cm⁻³. As mentioned previously, the deep well region 340 may include the well region 342. It should be appreciated that the well region 342 encircles the well region 324 from top view, so the well region 342 is disposed on both outer sides of the well region 324 in the cross-sectional view.

In some embodiments, the high-voltage well region 360 may laterally encircle the deep well region 340. Moreover, the high-voltage well region 360 may span across the high-voltage junction termination element 10A and the diode 10B. The doping concentration of the high-voltage well region 360 may be between 1.6×10¹⁶ cm⁻³ and 2.4×10¹⁶ cm⁻³. As mentioned previously, the high-voltage well region 360 may include the well region 362. It should be appreciated that the well region 362 encircles the well region 342 from top view, so the well region 362 is disposed on both outer sides of the well region 342 in the cross-sectional view.

In some embodiments, the deep well region 380 may span across the high-voltage junction termination element 10A and the junction field-effect transistor 10C. The deep well region 380 may be a loop that laterally encircles and is in direct contact with the high-side region 10A-1 from top view. The doping concentration of the deep well region 380 may be between 3.6×10¹⁶ cm⁻³ and 5.4×10¹⁶ cm⁻³. As mentioned previously, the deep well region 380 may include the well region 382. More specifically, the segment of the deep well region 380 at the high-voltage junction termination element 10A includes the well region 382 and the doped region 490 in the well region 382, and the segment of the deep well region 380 at the junction field-effect transistor 10C only includes the well region 382.

Referring to FIG. 3, the well region 302 may be formed in the epitaxial layer 300. In some embodiments, the well region 302 may be located in the junction field-effect transistor 10C. The well region 302 may be extended vertically from the upper surface of the epitaxial layer 300 into the epitaxial layer 300, and may be overlapped with the buried layer 240. The well region 302 may be the first conductive type (p-type). According to some embodiments of the present disclosure, the well region 302 may define the dimension of the channel region of the junction field-effect transistor 10C. The doping concentration of the well region 302 may be between 9.6×10¹⁷ cm⁻³ and 1.4×10¹⁸ cm⁻³. The thickness of the well region 302 may be between 0.2 μm and 0.6 μm. The lateral dimension of the well region 302 may be between 18 μm and 22 μm. The formation of the well region 302 may be similar to that of the high-voltage well region 320, the deep well region 340, the high-voltage well region 360, and the deep well region 380, and the details are not described again herein to avoid repetition.

Referring to FIG. 3, the well region 322 and the well region 324 may be disposed in the high-voltage well region 320. The well region 322 and the well region 324 may be extended vertically from the upper surface of the epitaxial layer 300 into the epitaxial layer 300. In the present embodiment, the well region 322 and the well region 324 are laterally spaced apart. According to some embodiments of the present disclosure, the well region 322 may be the second conductive type (n-type), while the well region 324 may be the first conductive type (p-type). The formation of the well region 322 and the well region 324 may be similar to that of the high-voltage well region 320, the deep well region 340, the high-voltage well region 360, and the deep well region 380, and the details are not described again herein to avoid repetition.

In some embodiments, the well region 322 may be overlapped with the buried layer 220. According to some embodiments of the present disclosure, the well region 322 may constitute the second conductive type (n-type) semiconductor layer of the diode 10B. The doping concentration of the well region 322 may be between 4.5×10¹⁶ cm⁻³ and 6.8×10¹⁶ cm⁻³. The thickness of the well region 322 may be between 1 μm and 2 μm.

In some embodiments, the well region 324 may be overlapped with the buried layer 220. According to some embodiments of the present disclosure, the well region 324 may constitute the first conductive type (p-type) semiconductor layer of the diode 10B. The doping concentration of the well region 324 may be between 3.6×10¹⁶ cm⁻³ and 5.4×10¹⁶ cm⁻³. The thickness of the well region 324 may be between 1 μm and 2 μm.

Still referring to FIG. 3, the well region 342 may be disposed in the deep well region 340. The well region 342 may be extended vertically from the upper surface of the epitaxial layer 300 into the epitaxial layer 300, and may be partially overlapped with the buried layer 220. The well region 342 may be the second conductive type (n-type). According to some embodiments of the present disclosure, the well region 342 may strengthen the isolation effect of the deep well region 340 in the horizontal direction. The doping concentration of the well region 342 may be between 4.5×10¹⁶ cm⁻³ and 6.8×10¹⁶ cm⁻³. The thickness of the well region 342 may be between 1 μm and 2 μm. The formation of the well region 342 may be similar to that of the high-voltage well region 320, the deep well region 340, the high-voltage well region 360, and the deep well region 380, and the details are not described again herein to avoid repetition.

Referring to FIGS. 3 and 4, the well region 362 and the doped region 450 may be disposed in the high-voltage well region 360. The well region 362 and the doped region 450 may be extended vertically from the upper surface of the epitaxial layer 300 into the epitaxial layer 300. In the present embodiment, the well region 362 and the doped region 450 are laterally spaced apart. According to some embodiments of the present disclosure, the well region 362 and the doped region 450 may both be the first conductive type (p-type). The formation of the well region 362 and the doped region 450 may be similar to that of the high-voltage well region 320, the deep well region 340, the high-voltage well region 360, and the deep well region 380, and the details are not described again herein to avoid repetition.

In some embodiments, the well region 362 may span across the high-voltage junction termination element 10A and the diode 10B. According to some embodiments of the present disclosure, the well region 362 may lower the resistance in series of the high-voltage well region 360. The doping concentration of the well region 362 may be between 3.6×10¹⁶ cm⁻³ and 5.4×10¹⁶ cm⁻³. The thickness of the well region 362 may be between 1 μm and 2 μm.

In some embodiments, the doped region 450 may be one of the elements of the ring shape of the high-voltage junction termination element 10A. According to some embodiments of the present disclosure, the doped region 450 and the doped region 440 may be the common ground terminal of the high-voltage junction termination element 10A. The doping concentration of the doped region 450 may be between 1.1×10²⁰ cm⁻³ and 1.7×10²⁰ cm⁻³. The thickness of the doped region 450 may be between 0.18 μm and 0.22 μm.

Still referring to FIGS. 3 and 4, the well region 382 may be disposed in the deep well region 380. The well region 382 may be extended vertically from the upper surface of the epitaxial layer 300 into the epitaxial layer 300. The well region 382 may be the second conductive type (n-type). According to some embodiments of the present disclosure, the well region 382 may lower the resistance in series of the deep well region 380. The doping concentration of the well region 382 may be between 4.5×10¹⁶ cm⁻³ and 6.8×10¹⁶ cm⁻³. The thickness of the well region 382 may be between 1 μm and 2 μm. The formation of the well region 382 may be similar to that of the high-voltage well region 320, the deep well region 340, the high-voltage well region 360, and the deep well region 380, and the details are not described again herein to avoid repetition.

Referring to FIGS. 2 and 3, the doped region 410 may be disposed in the well region 322. The doped region 410 may be extended vertically from the upper surface of the epitaxial layer 300 into the epitaxial layer 300. The doped region 410 may be the second conductive type (n-type). According to some embodiments of the present disclosure, the doped region 410 may serve as the cathode terminal of the diode 10B, and may be electrically coupled to the junction field-effect transistor 10C through the metal layer 920. The doping concentration of the doped region 410 may be between 4.0×10²⁰ cm⁻³ and 6.0×10²⁰ cm⁻³. The thickness of the doped region 410 may be between 0.09 μm and 0.11 μm. The formation of the doped region 410 may be similar to that of the high-voltage well region 320, the deep well region 340, the high-voltage well region 360, and the deep well region 380, and the details are not described again herein to avoid repetition.

Still referring to FIGS. 2 and 3, the doped region 420 may be disposed in the well region 324. The doped region 420 may be extended vertically from the upper surface of the epitaxial layer 300 into the epitaxial layer 300. As mentioned previously, the doped region 420 encircles the doped region 410. The doped region 420 may be the first conductive type (p-type). According to some embodiments of the present disclosure, the doped region 420 may serve as the anode terminal of the diode 10B. The doping concentration of the doped region 420 may be between 1.1×10²⁰ cm⁻³ and 1.7×10²⁰ cm⁻³. The thickness of the doped region 420 may be between 0.18 μm and 0.22 μm. The formation of the doped region 420 may be similar to that of the high-voltage well region 320, the deep well region 340, the high-voltage well region 360, and the deep well region 380, and the details are not described again herein to avoid repetition.

Referring to FIGS. 2 and 3, the doped region 430 may be disposed in the well region 342. The doped region 430 may be extended vertically from the upper surface of the epitaxial layer 300 into the epitaxial layer 300. As mentioned previously, the doped region 430 encircles the doped region 420. The doped region 430 may be the second conductive type (n-type). According to some embodiments of the present disclosure, the doped region 430 may also serve as the anode terminal of the diode 10B, and may be electrically connected with the doped region 420 through the metal layer 720. The doping concentration of the doped region 430 may be between 4.0×10²⁰ cm⁻³ and 6.0×10²⁰ cm⁻³. The thickness of the doped region 430 may be between 0.09 μm and 0.11 μm. The formation of the doped region 430 may be similar to that of the high-voltage well region 320, the deep well region 340, the high-voltage well region 360, and the deep well region 380, and the details are not described again herein to avoid repetition.

Referring to FIGS. 2-4, the doped region 440 may be disposed in the well region 362. The doped region 440 may be extended vertically from the upper surface of the epitaxial layer 300 into the epitaxial layer 300. As mentioned previously, the doped region 440 encircles the doped region 430, and may span across the high-voltage junction termination element 10A and the diode 10B. The doped region 440 may be the first conductive type (p-type). According to some embodiments of the present disclosure, since the doped region 440, the well region 362, the high-voltage well region 360, and the substrate 100 are the first conductive type (p-type), which may allow the high-voltage device 10 to be electrically ground from top or from bottom, and the doped region 440 may serve as the bulk of the substrate terminal. The doping concentration of the doped region 440 may be between 1.1×10²⁰ cm⁻³ and 1.7×10²⁰ cm⁻³. The thickness of the doped region 440 may be between 0.18 μm and 0.22 μm. The formation of the doped region 440 may be similar to that of the high-voltage well region 320, the deep well region 340, the high-voltage well region 360, and the deep well region 380, and the details are not described again herein to avoid repetition.

Referring to FIGS. 2 and 3, the doped region 460 may be disposed in the epitaxial layer 300. The doped region 460 may be extended vertically from the upper surface of the epitaxial layer 300 into the epitaxial layer 300. The doped region 460 may be the second conductive type (n-type). According to some embodiments of the present disclosure, the doped region 460 may serve as the source terminal of the junction field-effect transistor 10C, and may be electrically coupled to the diode 10B through the metal layer 920. Since the source terminal is the second conductive type (n-type), the junction field-effect transistor 10C may thus be the second conductive type (n-type). The doping concentration of the doped region 460 may be between 4.0×10²⁰ cm⁻³ and 6.0×10²⁰ cm⁻³. The thickness of the doped region 460 may be between 0.09 μm and 0.11 μm. The formation of the doped region 460 may be similar to that of the high-voltage well region 320, the deep well region 340, the high-voltage well region 360, and the deep well region 380, and the details are not described again herein to avoid repetition.

Referring to FIGS. 2 and 4, the conductive structure 470 may be disposed on the epitaxial layer 300. The conductive structure 470 may be extended from over the high-voltage well region 360 to over the epitaxial layer 300 in the horizontal direction. The conductive structure 470 is another element of the ring shape of the high-voltage junction termination element 10A. According to some embodiments of the present disclosure, the conductive structure 470 may modulate the underlying electric field. The thickness of the conductive structure 470 may be between 3.5 μm and 4.0 μm.

Materials of the conductive structure 470 may include amorphous silicon, polysilicon, poly-SiGe, metal nitride (such as titanium nitride (TiN), tantalum nitride (TaN), tungsten nitride (WN), titanium aluminum nitride (TiAlN), or the like), metal silicide (such as nickel silicide (NiSi), cobalt silicide (CoSi), tantalum silicon nitride (TaSiN), or the like), metal carbide (tantalum carbide (TaC), tantalum carbonitride (TaCN), or the like), metal oxide (such as titanium oxide (TiO) or the like), and metals. Metals may include cobalt (Co), ruthenium (Ru), aluminum (Al), palladium (Pd), platinum (Pt), tungsten (W), copper (Cu), titanium (Ti), tantalum (Ta), silver (Ag), gold (Au), nickel (Ni), manganese (Mn), zirconium (Zr), the like, a combination thereof, or a multiple layer thereof. The conductive structure 470 may be formed by physical vapor deposition (PVD), atomic layer deposition (ALD), plating, the like, or a combination thereof.

Referring to FIGS. 2 and 3, the doped region 480 may be disposed in the well region 302. The doped region 480 may be extended vertically from the upper surface of the epitaxial layer 300 into the epitaxial layer 300. The doped region 480 may be the first conductive type (p-type). According to some embodiments of the present disclosure, the doped region 480 may serve as the gate terminal of the junction field-effect transistor 10C. The doping concentration of the doped region 480 may be between 1.1×10²⁰ cm⁻³ and 1.7×10²⁰ cm⁻³. The thickness of the doped region 480 may be between 0.18 μm and 0.22 μm. The formation of the doped region 480 may be similar to that of the high-voltage well region 320, the deep well region 340, the high-voltage well region 360, and the deep well region 380, and the details are not described again herein to avoid repetition.

Referring to FIGS. 2 and 4, the doped region 490 may be disposed in the well region 382. The doped region 490 may be extended vertically from the upper surface of the epitaxial layer 300 into the epitaxial layer 300. As mentioned previously, the segment of the loop of the original doped region 490 at the junction field-effect transistor 10C is cut off, and only the segment of the doped region 490 at the high-voltage junction termination element 10A remains. The doped region 490 may be the second conductive type (n-type). According to some embodiments of the present disclosure, the doped region 490 may reduce the contact resistance of the deep well region 380. The doping concentration of the doped region 490 may be between 4.0×10²⁰ cm⁻³ and 6.0×10²⁰ cm⁻³. The thickness of the doped region 490 may be between 0.09 μm and 0.11 μm. The formation of the doped region 490 may be similar to that of the high-voltage well region 320, the deep well region 340, the high-voltage well region 360, and the deep well region 380, and the details are not described again herein to avoid repetition.

Referring to FIGS. 3 and 4, the isolation structure 500a, the isolation structure 500b, the isolation structure 500c, the isolation structure 500d, the isolation structure 500e, the isolation structure 500f, the isolation structure 500g, the isolation structure 500h, the isolation structure 500i, the isolation structure 500j, and the isolation structure 500k may be formed on the epitaxial layer 30. Specifically, since the manufacturing process involves high temperature treatment, the isolation structure 500a, the isolation structure 500b, the isolation structure 500c, the isolation structure 500d, the isolation structure 500e, the isolation structure 500f, the isolation structure 500g, the isolation structure 500h, the isolation structure 500i, the isolation structure 500j, and the isolation structure 500k are partially embedded into the epitaxial layer 300. According to some embodiments of the present disclosure, the isolation structure 500a, the isolation structure 500b, the isolation structure 500c, the isolation structure 500d, the isolation structure 500e, the isolation structure 500f, the isolation structure 500g, the isolation structure 500h, the isolation structure 500i, the isolation structure 500j, and the isolation structure 500k may be drift oxide (DOX) for insulating various conductive elements, to avoid electrical short of the high-voltage device 10 during operation.

As shown in FIG. 3, the segment of the doped region 440 at the diode 10B may be laterally located between the isolation structure 500a and the isolation structure 500b. The isolation structure 500b may laterally insulate the doped region 440 from the doped region 430. The doped region 430 may be laterally located between the isolation structure 500b and the isolation structure 500c. The doped region 420 may be laterally located between the isolation structure 500c and the isolation structure 500d. The doped region 410 may be laterally encircled by the isolation structure 500d. It is worth noted that the isolation structure 500c encircles the isolation structure 500d, the isolation structure 500b encircles the isolation structure 500c, and the isolation structure 500a encircles the isolation structure 500b from top view. The doped region 460 of the junction field-effect transistor 10C may be laterally located between the isolation structure 500a and the isolation structure 500e. The isolation structure 500e may laterally insulate the doped region 460 from the doped region 480. The doped region 480 may be laterally located between the isolation structure 500e and the isolation structure 500f. In conventional designs, the isolation structure 500f should be located between the doped region 480 and the doped region 490. Since the segment of the loop of the doped region 490 at the junction field-effect transistor 10C is cut off, the isolation structure 500f extends across the entire deep well region 380.

As shown in FIG. 4, the segment of the doped region 440 at the high-voltage junction termination element 10A may be laterally located between the isolation structure 500g and the isolation structure 500h. The isolation structure 500h may laterally insulate the doped region 440 from the doped region 450. The doped region 450 may be laterally located between the isolation structure 500h and the isolation structure 500i. The isolation structure 500i may laterally insulate the doped region 450 from the conductive structure 470. The conductive structure 470 may be laterally located between the isolation structure 500i and the isolation structure 500j. The isolation structure 500j may laterally insulate the conductive structure 470 from the segment of the doped region 490 at the high-voltage junction termination element 10A. As mentioned previously, the distance D1 is between the segment of the doped region 490 at the high-voltage junction termination element 10A and the conductive structure 470. The segment of the doped region 490 at the high-voltage junction termination element 10A may be laterally located between the isolation structure 500j and the isolation structure 500k.

In some embodiments, the isolation structure 500a, the isolation structure 500b, the isolation structure 500c, the isolation structure 500d, the isolation structure 500e, the isolation structure 500f, the isolation structure 500g, the isolation structure 500h, the isolation structure 500i, the isolation structure 500j, and the isolation structure 500k may be formed with silicon oxide (SiO), which may be local oxidation of silicon structures formed by thermal oxidation. In other embodiments, the isolation structure 500a, the isolation structure 500b, the isolation structure 500c, the isolation structure 500d, the isolation structure 500e, the isolation structure 500f, the isolation structure 500g, the isolation structure 500h, the isolation structure 500i, the isolation structure 500j, and the isolation structure 500k may be shallow trench isolation structures formed by etching, oxidation, and deposition processes.

Referring to FIGS. 3 and 4, after the isolation structure 500a, the isolation structure 500b, the isolation structure 500c, the isolation structure 500d, the isolation structure 500e, the isolation structure 500f, the isolation structure 500g, the isolation structure 500h, the isolation structure 500i, the isolation structure 500j, and the isolation structure 500k are formed, the interlayer dielectric layer 600 may be formed on the epitaxial layer 300. In some embodiments, the interlayer dielectric layer 600 may cover the epitaxial layer 300, the conductive structure 470, the isolation structure 500a, the isolation structure 500b, the isolation structure 500c, the isolation structure 500d, the isolation structure 500e, the isolation structure 500f, the isolation structure 500g, the isolation structure 500h, the isolation structure 500i, the isolation structure 500j, and the isolation structure 500k. In addition to providing mechanical protection and electrical insulation for the underlying structures, the interlayer dielectric layer 600 may also isolate conductive materials from different levels. Materials of the interlayer dielectric layer 600 may include silicon oxide, silicon nitride, silicon carbide, silicon oxynitride, silicon oxynitrocarbide (SiOₓN_{y}C_{1-x-y}, wherein x and y are in a range from 0 to 1), tetra ethyl ortho silicate (TEOS), undoped silicate glass, doped silicon oxide (such as boron-doped phosphosilicate glass (BPSG), fused silica glass (FSG), phosphosilicate glass (PSG), boron doped silicon glass (BSG), or the like), low-k dielectric materials, or the like.

The thickness of the interlayer dielectric layer 600 may be between 1000 μm and 1200 μm. The interlayer dielectric layer 600 may be formed by spin-on coating, chemical vapor deposition (CVD), high-density plasma chemical vapor deposition (HDP-CVD), plasma-enhanced chemical vapor deposition (PECVD), low-pressure chemical vapor deposition (LPCVD), flowable chemical vapor deposition (FCVD), sub-atmospheric chemical vapor deposition (SACVD), the like, or a combination thereof. Next, the planarization process (such as chemical mechanical polish) may be performed on the interlayer dielectric layer 600, allowing the interlayer dielectric layer 600 to have a planar surface.

Still referring to FIGS. 3 and 4, the via 620, the via 640, the via 660, the via 670, and the via 680 may be formed through the interlayer dielectric layer 600. The via 620, the via 640, the via 660, the via 670, and the via 680 may physically contact the doped region 420, the doped region 430, the doped region 440, the doped region 450, and the doped region 490, respectively. Furthermore, the metal layer 720 and the metal layer 740 may be formed on the interlayer dielectric layer 600. In some embodiments, the metal layer 720 is electrically coupled to the doped region 420 and the doped region 430 through the via 620 and the via 640, respectively, while the metal layer 740 is electrically coupled to the doped region 440, the doped region 450, and the doped region 490 through the via 660, the via 670, and the via 680, respectively. According to some embodiments of the present disclosure, the metal layer 720 may serve as the anode terminal of the diode 10B, while the metal layer 740 may serve as the electrical ground for the diode 10B. Furthermore, the segment of the metal layer 740 at the high-voltage junction termination element 10A may serve as the high-voltage power contact for the high-side region 10A-1. The via 620, the via 640, the via 660, the via 670, the via 680, the metal layer 720, and the metal layer 740 may be formed together, thus include the same material.

In some embodiments, the metal layer 740 may further include a spiral structure 745. The spiral structure 745 may be located above the isolation structure 500j. The spiral structure 745 may be one of the elements of the ring shape of the high-voltage junction termination element 10A, and may be extended in the spiral configuration. According to some embodiments of the present disclosure, the spiral structure 745 may function as field plates to manipulate the electric field of the underlying semiconductor layers. The width of every field plate element may be between 4 μm and 5 μm.

In some embodiments, the materials and the formation of the via 620, the via 640, the via 660, the via 670, the via 680, the metal layer 720, and the metal layer 740 may be similar to those of the conductive structure 470, and the details are not described again herein to avoid repetition. Initially, openings may be formed in the interlayer dielectric layer 600 to correspond to the doped region 420, the doped region 430, the doped region 440, the doped region 450, and the doped region 490. Next, the above materials may be blanket deposited on the interlayer dielectric layer 600 through the suitable deposition process mentioned above. The above materials may be formed on the surface of the interlayer dielectric layer 600, and may also fill into the openings to form the via 620, the via 640, the via 660, the via 670, and the via 680. The deposited film may be patterned by the lithography process, followed by the etching process to form the metal layer 720 and the metal layer 740 (including the spiral structure 745). The lithography process may include photoresist coating, soft baking, exposure, post-exposure baking, development, the like, or a combination thereof. The etching process may include dry etch process, wet etch process, the like, or a combination thereof. The thickness of the metal layer 720 and the metal layer 740 (including the spiral structure 745) may be between 0.4 μm and 0.5 μm.

Referring to FIGS. 3 and 4, the inter-metal dielectric layer 800 may be formed on the interlayer dielectric layer 600. In some embodiments, the inter-metal dielectric layer 800 may cover the interlayer dielectric layer 600, the metal layer 720, and the metal layer 740. According to some embodiments of the present disclosure, in addition to providing mechanical protection and electrical insulation for the underlying structures, the inter-metal dielectric layer 800 may also isolate conductive materials from different levels. The thickness of the inter-metal dielectric layer 800 may be between 500 μm and 700 μm. The materials and the formation of the inter-metal dielectric layer 800 may be similar to those of the interlayer dielectric layer 600, and the details are not described again herein to avoid repetition.

Still referring to FIGS. 3 and 4, the via 820, the via 830, the via 840, the via 850, the via 860, and the via 880 may be formed through the inter-metal dielectric layer 800. It is worth noted that the via 820, the via 840, and the via 860 further penetrates through the interlayer dielectric layer 600 to physically contact the doped region 410, the doped region 460, and the doped region 480, respectively. The via 830, the via 850, and the via 880 physically contact the metal layer 740. Furthermore, the metal layer 920, the metal layer 940, and the metal layer 960 may be formed on the inter-metal dielectric layer 800. In some embodiments, the metal layer 920 is electrically coupled to the doped region 410 and the doped region 460 through the via 820 and the via 840, respectively, the metal layer 940 is electrically coupled to the doped region 480 through the via 860, and the metal layer 960 corresponds to the via 660, the via 670, and the via 680 through the via 830, the via 850, and the via 880, respectively.

According to some embodiments of the present disclosure, the metal layer 920 may serve as the cathode terminal of the diode 10B, and may be electrically coupled to the junction field-effect transistor 10C, the metal layer 940 may serve as the gate terminal of the junction field-effect transistor 10C, and the metal layer 960 may serve as the high-voltage contact of the high-voltage junction termination element 10A. The thickness of the metal layer 920, the metal layer 940, and the metal layer 960 may be between 0.8 μm and 3.0 μm. Furthermore, the metal layer 960 may further include a spiral structure 965. The spiral structure 965 may be located above the spiral structure 745. The feature of the spiral structure 965 may be similar to that of the spiral structure 745, and the details are not described again herein to avoid repetition. Since the design rule of the spiral structure 965 is different from that of the spiral structure 745, the optimized spiral structure 965 may have different loop quantity (or the quantity of field plate elements). Moreover, the spacing between the spiral structure 745 may be between 0.5 μm and 0.8 μm, while the spacing between the spiral structure 965 may be different from that of the spiral structure 745 according to different thickness. The materials and the formation of the via 820, the via 830, the via 840, the via 850, the via 860, the via 880, the metal layer 920, the metal layer 940, and the metal layer 960 (including the spiral structure 965) may be similar to those of the via 620, the via 640, the via 660, the via 670, the via 680, the metal layer 720, and the metal layer 740, and the details are not described again herein to avoid repetition.

The high-voltage deice of the present disclosure integrates the high-voltage junction termination element, the embedded bootstrap diode with the isolation element, and the junction field-effect transistor together. However, the structural difference makes the entire circuit design becomes relatively complex, which in turn lowers the breakdown voltage of the high-voltage device. For example, two active regions need to be extended into the curved profile so they can be connected into the loop, the overlying metal layer corresponding to the corners of the loop may readily gather excessively high electric field due to the dimensional change, which in turn lowers the breakdown voltage. The high-voltage device of the present disclosure removes the segment of the loop where the corners are required to avoid the electric field crowding issue. Even if a portion of the loop is cut off, the loop can still remain conducting through other elements (such as the well region). When the electric field crowding issue is effectively alleviated, the overall breakdown voltage of the high-voltage device may be enhanced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A high-voltage device, comprising:
a diode;
a junction field-effect transistor (JFET) adjoining the diode and electrically coupled to the diode;
a high-voltage junction termination (HVJT) element electrically connected with the diode and the junction field-effect transistor, wherein the high-voltage junction termination element is a ring shape from top view, and a high-side region and a low-side region are respectively defined inside the ring shape and outside the ring shape; and
a first deep well region encircling the high-side region, comprising:
a first segment disposed in the high-voltage junction termination element, wherein the first segment comprises a well region and a doped region in the well region; and
a second segment disposed in the junction field-effect transistor, wherein the second segment comprises only the well region.

2. The high-voltage device of claim 1, further comprising:
a substrate disposed across the high-voltage junction termination element, the diode, and the junction field-effect transistor, and having a first conductive type; and
an epitaxial layer disposed across the high-voltage junction termination element, the diode, and the junction field-effect transistor, and is on the substrate, wherein the epitaxial layer has a second conductive type different from the first conductive type.

3. The high-voltage device of claim 2, wherein the first deep well region is disposed in the epitaxial layer, and has the second conductive type.

4. The high-voltage device of claim 2, wherein the diode further comprising:
a first high-voltage well region disposed in the epitaxial layer, and having the first conductive type;
a second deep well region disposed in the epitaxial layer and laterally encircling the first high-voltage well region, and having the second conductive type; and
a second high-voltage well region disposed in the epitaxial layer and laterally encircling the second deep well region, and having the first conductive type.

5. The high-voltage device of claim 4, wherein the diode further comprising a first buried layer disposed in the substrate, and the first buried layer is in direct contact with the first high-voltage well region and the second deep well region.

6. The high-voltage device of claim 4, wherein the first high-voltage well region comprises a first doped region and a second doped region, the second deep well region comprises a third doped region, and the second high-voltage well region comprises a fourth doped region.

7. The high-voltage device of claim 6, wherein the second doped region encircles the first doped region, the third doped region encircles the second doped region, and the fourth doped region encircles the third doped region.

8. The high-voltage device of claim 7, wherein the junction field-effect transistor further comprising:
a fifth doped region disposed in the epitaxial layer, and having the second conductive type;
a sixth doped region disposed in the epitaxial layer, and having the first conductive type; and
a second buried layer disposed in the substrate, and located under the sixth doped region.

9. The high-voltage device of claim 8, further comprising:
an interlayer dielectric (ILD) layer disposed on the epitaxial layer;
a first metal layer and a second metal layer disposed on the interlayer dielectric layer;
an inter-metal dielectric (IMD) layer covering the interlayer dielectric layer, the first metal layer, and the second metal layer; and
a third metal layer and a fourth metal layer disposed on the inter-metal dielectric layer.

10. The high-voltage device of claim 9, wherein the first metal layer is electrically coupled to the second doped region and the third doped region respectively through a first via and a second via.

11. The high-voltage device of claim 9, wherein the second metal layer is electrically coupled to the fourth doped region through a third via.

12. The high-voltage device of claim 9, wherein the third metal layer is electrically coupled to the first doped region and the fifth doped region respectively through a fourth via and a fifth via.

13. The high-voltage device of claim 9, wherein the fourth metal layer is electrically coupled to the sixth doped region through a sixth via.

14. A method of forming a high-voltage device, comprising:
providing a substrate;
forming an epitaxial layer on the substrate;
forming a first high-voltage well region, a first deep well region encircling the first high-voltage well region, and a second high-voltage well region encircling the first deep well region in a first region of the epitaxial layer;
forming a first doped region and a second doped region encircling the first doped region in the first high-voltage well region;
forming a third doped region in the first deep well region, wherein the third doped region encircles the second doped region;
forming a fourth doped region in the second high-voltage well region;
forming a fifth doped region and a sixth doped region in a second region of the epitaxial layer, wherein the second region laterally adjoins the first region;
extending a side of the fourth doped region outward into a third region of the epitaxial layer to form a loop, wherein the second region is in the loop;
forming a second deep well region in the loop, wherein the second deep well region extends along an inner side of the loop and across the second region;
forming a seventh doped region in the second deep well region, wherein the seventh doped region extends along a profile of the second deep well region; and
cutting off a portion of the seventh doped region in the second deep well region across the second region.

15. The method of claim 14, wherein the first region, the second region, and the third region respectively define a diode, a junction field-effect transistor, and a high-voltage junction termination element.

16. The method of claim 14, further comprising forming a first buried layer and a second buried layer in the substrate, the first buried layer and the second buried layer respectively extend into the first region and the second region of the epitaxial layer.

17. The method of claim 14, further comprising forming an eighth doped region and a conductive structure between the loop of the third region and the second deep well region.

18. The method of claim 17, wherein a first distance is between the conductive structure and the seventh doped region.

19. The method of claim 18, wherein before cutting off the portion of the seventh doped region across the second region, a second distance is between a portion of the sixth doped region and a portion of the seventh doped region across the second region, and the second distance is different from the first distance.

20. The method of claim 17, wherein the first doped region of the first region is electrically coupled to the fifth doped region of the second region through a metal layer.
